(19) United States
(12) Patent Application Publication
(10) Pub. No.: US 2003/0021430 A1
(43) Pub. Date: Jan. 30, 2003

(54) Multifunctional power supply unit for a portable game machine

(76) Inventor: Fu-I Yang, Tao-Yuang City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/910,892

(22) Filed: Jul. 24, 2001

(51) Int. Cl. H03F 21/00

(52) U.S. Cl. 381/120

(57) ABSTRACT

The present invention relates to a multifunctional power supply unit for a Game Boy machine comprising a housing that is engaged in a battery compartment and in which a constant voltage loop, a rechargeable battery set, a DC socket, a positive and a negative poles, an amplifying circuit and a speaker are received. The positive and negative poles are positioned at the side of the housing and in contact with the electric pole inside of the battery compartment. The constant voltage loop is disposed on a circuit board and connected with the DC socket to get the power source from the externally connected transformer or the vehicle and to stabilize it at certain voltage range required by the game machine. Thereafter, a connection to the positive and negative poles takes place for supplying a stable voltage to the game machine. Besides, the output of the constant voltage loop is in connection with the rechargeable battery set for the charging purpose. The sound amplifying circuit is connected with the output of the constant voltage loop while a sound signal connecting cable is in connection with a sound signal output interface so that the signal is amplified to be connected to the speaker for output.

### BACKGROUND OF THE INVENTION

1. Field of the Invention

The present invention relates to a multifunctional power supply unit for a portable game machine, and more particularly, to a multifunctional power supply unit applicable to the commercially available transformer or the vehicle power source. Besides, a rechargeable battery and a speaker are installed in the present invention.

2. Description of the Prior Art

As shown in FIGS. 1 and 2, the Nintendo Game Boy machine (M), has, in addition to the battery-powered design, a power transforming unit (not shown) installed in the battery compartment 1. However, the original battery cover 11 and the dry batteries B have to be removed. Therefore, the power transforming unit is useless when without connection to the mains socket, and the game machine has to be changed to be battery-powered. This is very inconvenient. Besides, the components of the power transforming unit are so complicated that it's not compatible with the commercially available transformers, but only applicable to a special adapter of Nintendo Game machine. Hence, it's inconvenient for the user to carry this special adapter when going out. Moreover, the power transforming unit is not compatible with other transformers or the vehicle cigarette lighter, thereby causing much trouble. Not using the power transforming unit, the game machine has to be powered by batteries which only supply power for few hours operation, thereby causing a considerable cost burden.

In addition, the volume of the game machine is not enough to create a sound shaking effect. Particularly, the tiny sound of game can't present the situation closely fought by each other so that the exciting effect of game is lost.

### SUMMARY OF THE INVENTION

It is a primary object of the present invention to provide a multifunctional power supply unit for a portable game machine which is applicable to the commercially available transformer or the cigarette light outlet. Meanwhile, the game machine can be powered by a built-in rechargeable battery. Accordingly, the using convenience is much enhanced.

It is another object of the present invention to provide a multifunctional power supply unit for a portable game machine in which a built-in speaker is used to amplify the sound for increasing the sound shaking effect.

### BRIEF DESCRIPTION OF THE DRAWINGS

The accomplishment of this and other objects of the invention will become apparent from the following description and its accompanying drawings of which:

FIG. 1 is a perspective view of a commercially available game machine;

FIG. 2 is a perspective view of a battery compartment of the commercially available game machine;

FIG. 3 is a perspective view of the present invention in combination with the commercially available game machine;

FIG. 4 is another perspective view of the present invention in combination with the commercially available game machine;

FIG. 5 is a sectional view of the present invention in combination with the commercially available game machine;

FIG. 6 is another sectional view of the present invention in combination with the commercially available game machine;

FIG. 7 is a block diagram showing the operating sequence of the present invention; and

FIG. 8 is an internal circuit diagram of the present invention.

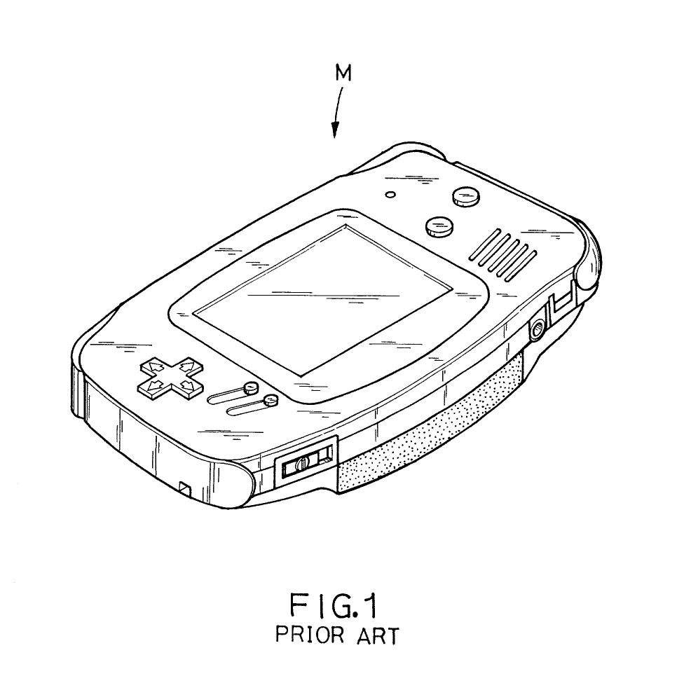

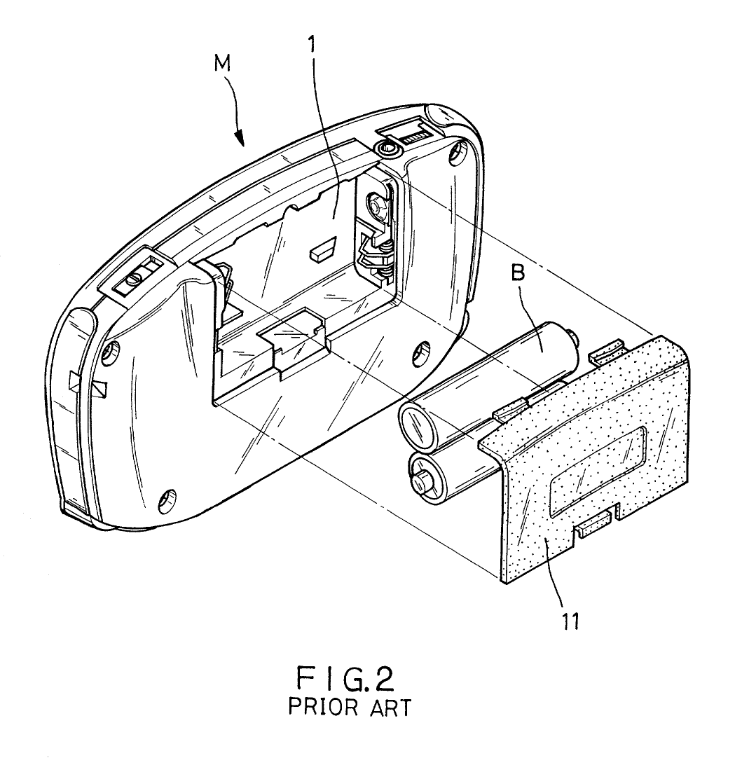

### DETAILED DESCRIPTION OF THE PREFERRED EMBODIMENT

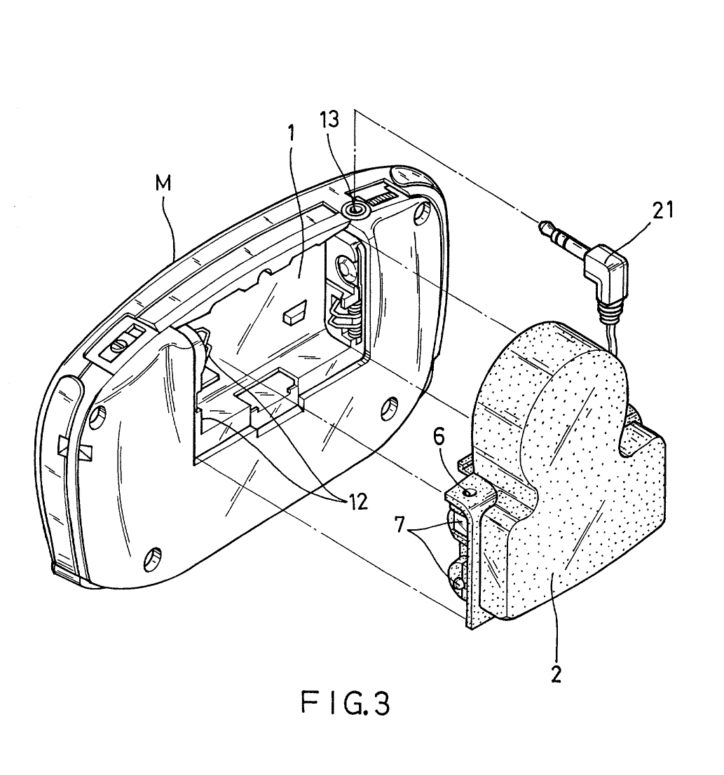

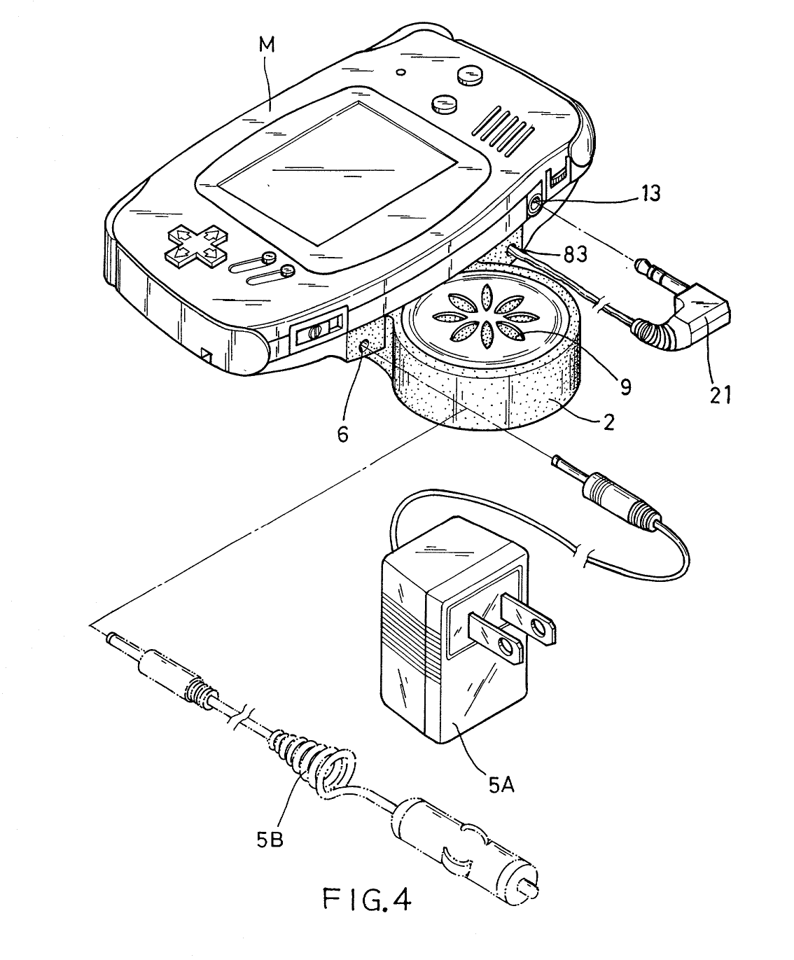

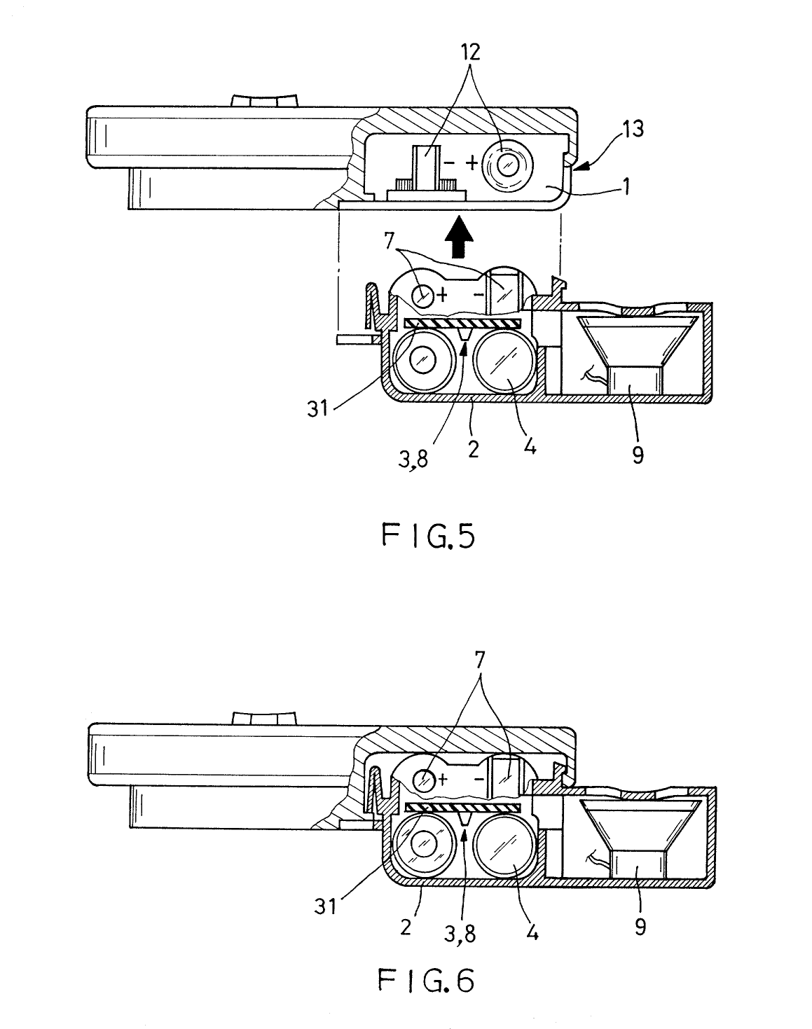

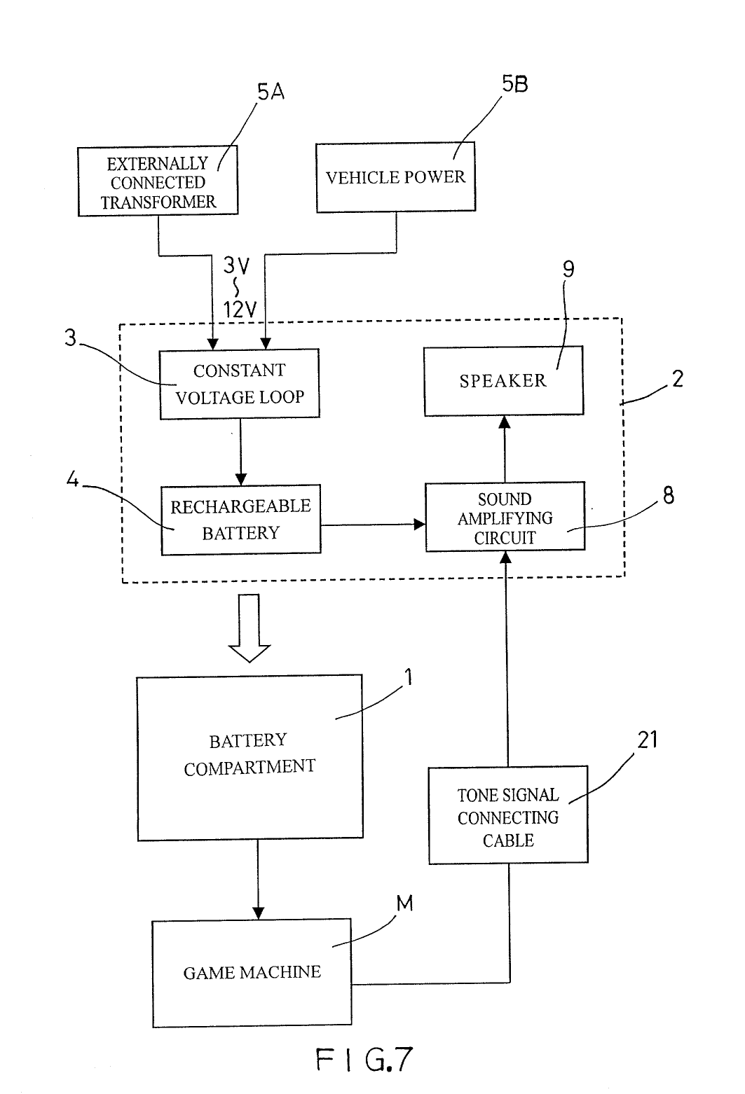

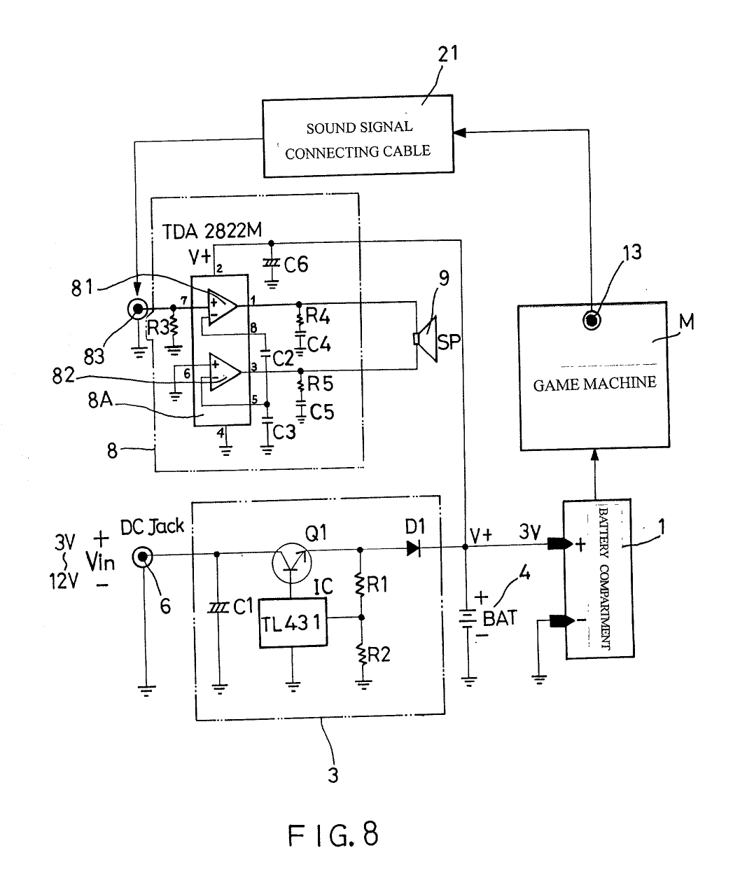

First of all, referring to FIGS. 3 through 8, the multifunctional power supply unit for a portable game machine disclosed by the present invention has a housing 2 that is engaged in a battery compartment 1 of a Game Boy machine M and in which a constant voltage loop 3, a rechargeable battery set 4, a DC socket 6, a positive and a negative poles 7, an amplifying circuit 8 and a speaker 9 are received. The positive and negative poles 7 are positioned at the side of the housing 2 and in contact with the electric pole 12 inside of the battery compartment 1.

The constant voltage loop 3 is disposed on a circuit board 31 and connected with the DC socket 6 to get the power source from the externally connected transformer 5A or the vehicle and to stabilize it at certain voltage range required by the game machine. Thereafter, a connection to the positive and negative poles 7 takes place for supplying a stable voltage to the game machine M. Besides, the output of the constant voltage loop 3 is in connection with the rechargeable battery set 4 for the charging purpose.

The sound amplifying circuit 8 is connected with the output of the constant voltage loop 3 while a sound signal connecting cable 21 is in connection with a sound signal output interface 13 so that the signal is amplified to be connected to the speaker 9 for output.

The constant voltage loop 3 on the circuit board 31 includes a filter capacitance C1, a voltage-stabilizing integrated circuit, an n-p-n power transistor Q1, a diode D1 and two current-limiting resistances R1, R2. A base electrode of the power transistor Q1 is connected with the voltage-stabilizing integrated circuit marked by the model No. of TL431. A collector and an emitter of the power transistor Q1 are connected between the DC power source input and the diode D1. Provided between the power transistor Q1 and the diode D1 are the two resistances R1, R2 between which the voltage-stabilizing integrated circuit is connected, thereby creating the constant voltage loop to control the DC voltage output.

Only when the DC voltage inputted from the DC socket 6 is kept between 3V and 12V, the constant voltage loop 3 can be utilized to control a stable output of the DC voltage (ca. 3V) for the use of the battery compartment 1. Meanwhile, the rechargeable battery set 4 is in connection with the stable voltage output and positioned behind the diode D1 for recharging. When the power source of the DC socket 6 is stopped, the rechargeable battery set 4 can be used to supply 3V stable power source to the battery compartment 1.

Connected to a positive pole line of the constant voltage loop 3 is the ton amplifying circuit 8 which is marked by the type model of TDA2822M for the amplifying integrated circuit 8A which features a low operating voltage (ca. 2V). Thereafter, the voltage (3V) supplied to the battery compartment 1 of the game machine is much enough for actuating the amplifying circuit 8. The amplifying circuit 8 comprises an amplifying integrated circuit 8A in which two amplifiers 81, 82 are installed. The first and third connecting pins of the amplifiers 81, 82 are series-connected with a speaker 9 while the seventh pin of the amplifier 81 is connected to a sound signal input 83 through which the sound signal from the sound signal output interface 13 of the game machine M and the sound signal connecting cable 21 will be amplified to create a stereo sound with shaking effect. Moreover, the negative pole of the amplifiers 81, 82 is connected to two capacitance units C2, C3. The series-connection circuit of the amplifiers 81, 82 and the speaker 9 contains a filter circuit comprising a resistance R4, a capacitance C4, a resistance R5 and a capacitance C5. A capacitance C6 is provided between the sound signal input 83 and the amplifier 81. The original sound of the game machine M will be amplified by means of the sound amplifying circuit 8 consisting of the aforementioned components. To fit the sound amplifying circuit 8 to the housing 2 will enhance the sound effect. Therefore, the rechargeable power supply unit of the present invention can not only directly supply the stable power required by the battery compartment 1 of the game machine. Besides, it's applicable when the input voltage of the transformer 5A lies between 3V and 12V. Moreover, the power supply 5B of 12V from the cigarette lighter outlet in automobile is also applicable to the portable game machine. Thus, the using convenience of the present invention is much improved. Furthermore, it's chargeable while using so that the game machine can be battery-operated when the user goes out and has no available external power source. Accordingly, it's convenient without replacing the batteries. Moreover, the present invention can enhance the using convenience and the sound-shaking effect. Many changes and modifications in the above-described embodiment of the invention can, of course, be carried out without departing from the scope thereof. Accordingly, to promote the progress in science and the useful arts, the invention is disclosed and is intended to be limited only by the scope of the appended claims.

What is claimed is:

1. A multifunctional power supply unit for a portable game machine comprising a housing insertable in a battery compartment of a Game Boy machine and having a constant voltage loop, a rechargeable battery set, a DC socket, a positive and a negative poles, an amplifying circuit and a speaker therein, wherein this improvement is characterized by:
said constant voltage loop disposed on a circuit board and connected with said DC socket to get the power source from the externally connected transformer or the vehicle and to stabilize it at certain voltage range required by said game machine, whereupon a connection to said positive and negative poles takes place for supplying the stable voltage to said game machine while the output of said constant voltage loop is in connection with said rechargeable battery set for the charging purpose; and
said sound amplifying circuit connected with the output of said constant voltage loop while a sound signal connecting cable is in connection with a sound signal output interface so that the signal is amplified to be connected to said speaker for output.

2. A multifunctional power supply unit for a portable game machine as recited in claim 1, wherein said constant voltage loop on said circuit board includes a filter capacitance, a voltage-stabilizing integrated circuit, an n-p-n power transistor, a diode and two current-limiting resistances, and
wherein a base electrode of said power transistor is connected with said voltage-stabilizing integrated circuit, and
wherein a collector and an emitter of said power transistor are connected between said DC power source input and said diode; and
wherein provided between said power transistor and said diode are said two resistances between which said voltage-stabilizing integrated circuit is connected.

3. A multifunctional power supply unit for a portable game machine as recited in claim 1, wherein said amplifying circuit comprises an amplifying integrated circuit in which two amplifiers are installed, and wherein the first and third connecting pins of said amplifiers are series-connected with a speaker while the seventh pin of the amplifier is connected to a sound signal input through which the sound signal from said sound signal output interface of said game machine and said sound signal connecting cable will be amplified to create a stereo sound with shaking effect, and wherein the negative pole of said amplifiers is connected to two capacitance units, and wherein the series-connection circuit of said amplifiers and said speaker contains a filter circuit comprising a resistance, a capacitance, a resistance and another capacitance, and wherein a further capacitance is provided between said sound signal input and said amplifier.
